(19) United States
(12) Patent Application Publication
(10) Pub. No.: US 2026/0268044 A1
(43) Pub. Date: Sep. 10, 2026

(54) CHEMICAL PROCESS OPTIMIZATION SYSTEM AND METHOD BASED ON SERIAL INTEGRATION MODELS

(71) Applicant: NAN YA PLASTICS CORPORATION, TAIPEI (TW)

(72) Inventors: CHING-YAO YUAN, TAIPEI (TW); CHUNG-YU CHEN, TAIPEI (TW); YI-CHENG LI, TAIPEI (TW); FANG-LING HSU, New Taipei City (TW)

(21) Appl. No.: 19/198,133

(22) Filed: May 5, 2025

(30) Foreign Application Priority Data
Mar. 6, 2025 (TW) 114108219

(51) Int. Cl. G06F 30/27; G06F 16/25

(52) U.S. Cl. CPC G06F 30/27; G06F 16/252

(57) ABSTRACT

A chemical process optimization system and method based on serial integration models are provided. The system includes: a big data database construction module, a serial artificial intelligence training module, and a profit optimization module. The big data database construction module is configured to construct a big data database by receiving historical data from a chemical production site and integrating the historical data with a chemical theoretical model. The serial artificial intelligence training module includes a first artificial intelligence training model based on linear regression and a second artificial intelligence training model based on nonlinear regression, configured to perform model training during a training stage and to output a predicted result based on a process parameter and an intermediate parameter during a prediction stage. The profit optimization module has a nature-inspired algorithm, configured to calculate a production decision by combining the predicted result with an economic parameter.

### CROSS-REFERENCE TO RELATED PATENT APPLICATION

This application claims the benefit of priority to Taiwan Patent Application No. 114108219, filed on Mar. 6, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chemical process optimization system, and more particularly to a chemical process optimization system and a chemical process optimization method based on serial integration models.

### BACKGROUND OF THE DISCLOSURE

In chemical industry, synthesis gas (i.e., syngas) is a critical intermediate used in production of various chemical products such as ammonia, methanol, hydrogen, and fuel, and has widespread industrial applications.

Conventional syngas production processes generally rely on human experience for adjusting operating parameters. However, due to the inherent nonlinear characteristics of chemical processes, the high dimensionality of operating parameters, and external factors such as fluctuations in raw material costs and market demand, conventional adjustment methods exhibit the following drawbacks:

Lack of timeliness: Operators often find it difficult to respond in real time to changes in market demand, raw material prices, and utility costs, making it challenging to promptly determine optimal operating conditions.

Limited accuracy: Chemical processes typically involve nonlinear and interdependent parameter relationships. Relying solely on human experience is insufficient for accurately assessing the impact of such complex factors on production yield and product quality.

High resource consumption: In the absence of an accurate condition optimization mechanism, excessive use of fuel and steam is common, leading to increased operational costs and resource waste.

Lack of intelligent technology integration: Conventional methods have not widely incorporated chemical simulation software or big data analytics, and fail to provide real-time, scientifically-grounded optimization recommendations.

### SUMMARY OF THE DISCLOSURE

In response to the above-referenced technical inadequacies, the present disclosure provides a chemical process optimization system and a chemical process optimization method based on serial integration models.

In order to solve the above-mentioned problems, one of the technical aspects adopted by the present disclosure is to provide a chemical process optimization system based on serial integration models. The chemical process optimization system includes a big data database construction module, a serial artificial intelligence training module, and a profit optimization module.

The big data database construction module has a chemical theoretical model built therein. The big data database construction module is configured to receive historical data collected from a chemical production site under a database construction operating environment, and to perform data fitting between the historical data and the chemical theoretical model so as to construct a big data database.

The serial artificial intelligence training module is connected to the big data database. During a training stage, the serial artificial intelligence training module is configured to perform model training through training data in the big data database. The serial artificial intelligence training module includes: a first artificial intelligence training model and a second artificial intelligence training model. The first artificial intelligence training model is constructed based on a linear regression algorithm. The second artificial intelligence training model is constructed based on a nonlinear regression algorithm. During a prediction stage, the first artificial intelligence training model receives at least a process parameter that is externally input and outputs at least an intermediate parameter. The second artificial intelligence training model receives the process parameter and further receives the intermediate parameter during the prediction stage so as to calculate and output at least a predicted result.

The profit optimization module has a nature-inspired algorithm built therein. The profit optimization module is connected to the serial artificial intelligence training module. The profit optimization module is configured to receive at least an economic parameter that is externally input. The profit optimization module is configured to utilize the nature-inspired algorithm to calculate a production decision based on a demand amount of a product, in combination with the economic parameter and the predicted result, and further considering at least an operational boundary constraint.

Preferably, the chemical process optimization system further includes a visualization interface module that is configured to allow a user to input the demand amount of the product in real time, and to visually present the production decision of the profit optimization module.

Preferably, the chemical theoretical model is implemented using a chemical simulation software with physical meaning, and the chemical simulation software is at least one of Aspen Plus, Aspen HYSYS, PRO/II, and Petro-SIM; in which the historical data is historical production data collected from the chemical production site, and the training data includes process data, intermediate data, and product data.

Preferably, the first artificial intelligence training model adopts at least one of ordinary least squares (OLS), gradient descent, and regularized linear regression.

Preferably, the second artificial intelligence training model adopts at least one of polynomial regression, support vector regression (SVR), decision tree regression, random forest regression, neural network regression, nonlinear least squares, gaussian process regression (GPR), and XGBoost Regressor.

Preferably, the nature-inspired algorithm is at least one of genetic algorithm (GA), particle swarm optimization (PSO), ant colony optimization (ACO), and simulated annealing (SA).

Preferably, during the training stage, the serial artificial intelligence training module is configured to train and cross-validate the first artificial intelligence training model and the second artificial intelligence training model separately by using the training data from the big data database.

Preferably, in the serial artificial intelligence training module, the process parameter includes at least one of a light-oil feed amount, a steam usage amount, a reaction temperature, a reaction pressure, and a carbon dioxide reflux amount; in which the intermediate parameter includes at least one of a reaction rate and a reaction conversion rate, and the predicted result includes at least one of a product yield and a product production rate.

Preferably, the economic parameter includes at least one of a revenue parameter and an expenditure parameter; in which the revenue parameter corresponds to a product selling price, and the expenditure parameter includes at least one of a raw material price and an energy cost.

Preferably, the profit optimization module is configured to analyze and output the production decision through a recursive iteration process based on a profit maximization function or a cost minimization function.

In order to solve the above-mentioned problems, another one of the technical aspects adopted by the present disclosure is to provide a chemical process optimization method based on serial integration models. The method includes: using a big data database construction module, having a chemical theoretical model built therein, to receive historical data collected from a chemical production site under a database construction operating environment, and to perform data fitting between the historical data and the chemical theoretical model, so as to construct a big data database.

The chemical process optimization method further includes: connecting a serial artificial intelligence training module to the big data database, and performing model training through training data in the big data database during a training stage; and connecting a profit optimization module having a nature-inspired algorithm built therein to the serial artificial intelligence training module.

The serial artificial intelligence training module includes: a first artificial intelligence training model and a second artificial intelligence training model that are connected in series.

The first artificial intelligence training model is constructed based on a linear regression algorithm, and the second artificial intelligence training model is constructed based on a nonlinear regression algorithm. During a prediction stage, the first artificial intelligence training model receives at least a process parameter that is externally input and outputs at least an intermediate parameter. The second artificial intelligence training model receives the process parameter and further receives the intermediate parameter during the prediction stage so as to calculate and output at least a predicted result.

The profit optimization module is configured to receive at least an economic parameter that is externally input, and the profit optimization module is configured to utilize the nature-inspired algorithm to calculate a production decision based on a demand amount of a product, in combination with the economic parameter and the predicted result, and considering at least an operational boundary constraint.

Preferably, the chemical process optimization method further includes: using a visualization interface module to allow a user to input the demand amount of the product in real time, and visually present the production decision of the profit optimization module.

Therefore, the chemical process optimization system and method provided by the present disclosure can achieve accurate modeling of chemical processes and maximization of economic benefits by virtue of “the big data database construction module, the serial artificial intelligence training module, and the profit optimization module.” The coordinated operation of the various modules addresses existing issues in conventional chemical processes, such as data incompleteness, inaccurate modeling, and low decision-making efficiency.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of a chemical process optimization system according to one embodiment of the present disclosure; and

FIG. 2 is a flowchart of a chemical process optimization method according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Chemical Process Optimization System Based on Serial Integration Models

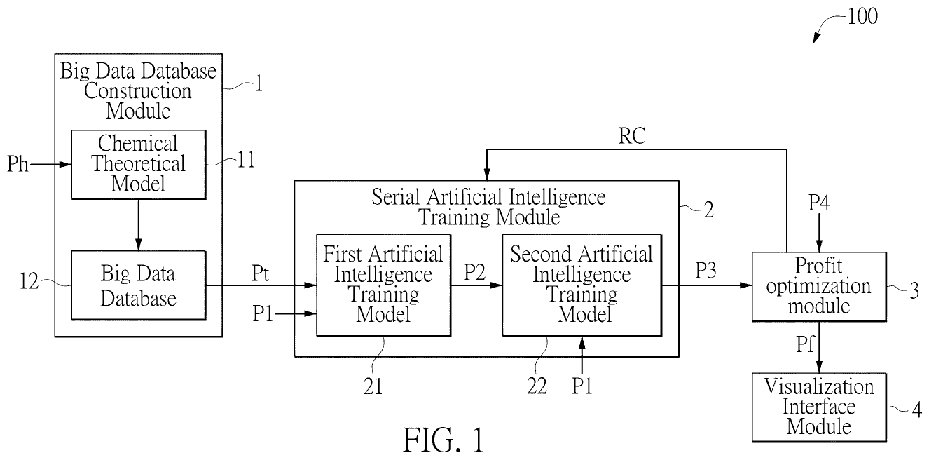

Referring to FIG. 1, an embodiment of the present disclosure provides a chemical process optimization system 100 based on serial integration models, which is configured to provide production decisions for chemical process optimization and to achieve maximized economic benefits. The chemical process optimization system 100 of the embodiment of the present disclosure can be used for optimizing production decisions of a synthesis gas chemical process, but the present disclosure is not limited thereto.

In order to achieve the above objective, the chemical process optimization system 100 based on the serial integration models according to the embodiment of the present disclosure includes a big data database construction module 1, a serial artificial intelligence training module 2, a profit optimization module 3, and a visualization interface module 4.

### Big Data Database Construction Module

The big data database construction module 1 has a chemical theoretical model 11 built therein. The chemical theoretical model is constructed based on fundamental theories, such as mass balance, energy balance, and reaction kinetics. The big data database construction module 1 is configured to receive historical data Ph (i.e., historical production data) collected from a chemical production site under a database construction operating environment, and to perform data fitting between the historical data Ph and the chemical theoretical model 11, so as to construct a big data database 12 with physical significance.

The big data database 12 includes training data Pt that can be used for subsequent training by the serial artificial intelligence training module 2.

In some embodiments of the present disclosure, the chemical theoretical model 11 is implemented by using chemical simulation software with physical significance. The chemical simulation software is at least one of Aspen Plus, Aspen HYSYS, PRO/II, and Petro-SIM. The chemical simulation software is supplemented by equations for mass balance, energy balance, and reaction kinetics to simulate production results under different operating conditions, thereby compensating for measurement limitations in actual production environments.

The historical data Ph (i.e., historical production data) is obtained from actual operational records of a chemical plant. Taking a synthesis gas process as an example, the historical data Ph can include: a light-oil feed amount, a steam usage amount, a reaction temperature, a reaction pressure, a carbon dioxide reflux amount, and the yield or production rate of the corresponding product (e.g., synthesis gas).

The training data Pt in the big data database 12 is obtained by performing data fitting between the historical data Ph and the chemical theoretical model 11.

In the present embodiment, the training data Pt includes process data, intermediate data, and product data. Taking a synthesis gas process as an example, the process data can include process conditions, such as a light-oil feed amount, a steam usage amount, a reaction temperature, a reaction pressure, and/or a carbon dioxide reflux amount, which can be controlled by an operator. The intermediate data can include chemical reaction kinetics data during the reaction process, such as a reaction rate or a reaction conversion rate. The product data can include the yield or production rate of the synthesis gas. It is worth mentioning that the intermediate data may not be directly available from the historical production data collected from the chemical production site. However, in the embodiment of the present disclosure, the intermediate data can be obtained by performing data fitting through the chemical theoretical model 11, but the present disclosure is not limited thereto.

In one embodiment of the present disclosure, in order to ensure prediction accuracy of the serial artificial intelligence training module 2 connected thereto, the big data database construction module 1 can further perform a data validation and cleaning operation, including: detecting and removing outliers in the historical data Ph; supplementing missing values in the historical data Ph or estimating replacements using statistical methods; and filtering out samples from the historical data Ph that are not physically meaningful or do not match real production scenarios. However, the present disclosure is not limited to performing the above-mentioned data validation and cleaning operation.

The big data database 12 constructed by the big data database construction module 1 of the embodiment of the present disclosure covers multiple scenarios and has physical significance, which can serve as training foundation for the serial artificial intelligence training module 2. By integrating chemical theoretical foundations with historical experience, the reliability and physical operability of the model can be significantly enhanced. In other words, since actual production sites do not directly record reaction data under all operating conditions (e.g., insufficient yield or reaction data), the embodiment of the present disclosure utilizes theoretical simulation to preliminarily construct the big data database to compensate for such insufficiencies.

In terms of hardware, the big data database construction module 1 is suitable for deployment on high-performance computing equipment, such as servers or workstations equipped with multi-core processors, large-capacity memory (at least 64 GB), and high-performance storage devices (e.g., solid-state drives or distributed storage systems). The system also supports running large-scale data processing frameworks to process the historical data from the chemical production site and to perform data fitting for constructing the big data database with physical significance.

### Serial Artificial Intelligence Training Module

Further referring to FIG. 1, the serial artificial intelligence training module 2 includes a first artificial intelligence training model 21 and a second artificial intelligence training model 22, which are connected in series.

The first artificial intelligence training model 21 is a linear regression artificial intelligence model, and the second artificial intelligence training model 22 is a nonlinear regression artificial intelligence model.

In some embodiments of the present disclosure, the first artificial intelligence training model 21 and the second artificial intelligence training model 22 can be implemented as a two-stage artificial intelligence training model based on the Python language, but the present disclosure is not limited thereto.

The first artificial intelligence training model 21 is constructed based on a linear regression algorithm and can be implemented by using at least one of ordinary least squares (OLS), gradient descent, regularized linear regression, or a combination thereof, to accommodate different data characteristics and model requirements.

The second artificial intelligence training model 22 is constructed based on a nonlinear regression algorithm and can be implemented by using at least one of polynomial regression, support vector regression (SVR), decision tree regression, random forest regression, neural network regression, nonlinear least squares, gaussian process regression (GPR), or XGBoost regressor, or a combination thereof, in order to accommodate various nonlinear data and to enhance prediction accuracy and applicability.

During a training stage, the serial artificial intelligence training module 2 is configured to receive the training data Pt (including process data, intermediate data, and product data) from the big data database 12 provided by the big data database construction module 1, and perform individual training and cross-validation on the first artificial intelligence training model 21 and the second artificial intelligence training model 22. Accordingly, the serial artificial intelligence training module 2 is in data connection with the big data database 12 of the big data database construction module 1 to perform precise modeling and prediction of production conditions.

In one embodiment of the present disclosure, the second artificial intelligence training model 22 can further perform hyper-parameter tuning, such as tree depth or learning rate in XGBoost, but the present disclosure is not limited thereto.

Further, during a prediction stage, the first artificial intelligence training model 21 of the serial artificial intelligence training module 2 receives at least a process parameter P1 externally input and performs computation using a model constructed based on training data Pt through a linear regression algorithm, thereby outputting at least an intermediate parameter P2.

In some embodiments of the present disclosure, taking a synthesis gas process as an example, the externally input process parameter P1 can be an operator-controllable process condition such as a light-oil feed amount, a steam usage amount, a reaction temperature, a reaction pressure, and/or a carbon dioxide reflux amount.

The intermediate parameter P2 can be chemical reaction kinetics data during the reaction process and can include at least one of a reaction rate and a reaction conversion rate.

The first artificial intelligence training model 21 is capable of rapidly processing quasi-linear parameter relationships. In other words, the first artificial intelligence training model 21 can quickly compute the intermediate parameter P2 based on the process parameter P1, thereby providing an initial reference for the subsequent second artificial intelligence training model 22 (i.e., nonlinear model) so as to reduce the computational complexity required by the second artificial intelligence training model 22.

During the prediction stage, the second artificial intelligence training model 22 also receives the process parameter P1 externally input (e.g., a light-oil feed amount, a steam usage amount, a reaction temperature, a reaction pressure, and/or a carbon dioxide reflux amount), and further receives the intermediate parameter P2 (e.g., a reaction rate or a reaction conversion rate) output from the first artificial intelligence training model 21. Then, the second artificial intelligence training model 22 performs advanced computation using a model constructed based on the training data Pt through a nonlinear regression algorithm, and finally outputs a predicted result P3 (e.g., product yield or production rate).

The second artificial intelligence training model 22 is capable of processing high-dimensional nonlinear data and demonstrates strong tolerance to missing values and noise, thereby achieving higher prediction accuracy.

As described above, the first artificial intelligence training model 21, which is based on a linear regression algorithm (e.g., ordinary least squares, gradient descent, or regularized methods), is suitable for processing data patterns in which the input data and output data have clear linear relationships. The second artificial intelligence training model 22, which is based on a nonlinear regression algorithm (e.g., support vector regression, decision tree regression, random forest regression, or neural network regression), is used to capture more complex nonlinear relationships between input data and output data.

The serial artificial intelligence training module 2 according to the embodiment of the present disclosure is composed of the first artificial intelligence training model 21 (i.e., the linear regression model) and the second artificial intelligence training model 22 (i.e., the nonlinear regression model), which cooperate in both the training stage and the prediction stage.

During the training stage, the serial artificial intelligence training module 2 receives the training data Pt (e.g., the process data, the intermediate data, and the product data) from the big data database construction module 1. The first artificial intelligence training model 21 and the second artificial intelligence training model 22 are then trained and cross-validated to complete the model construction.

During the prediction stage, the first artificial intelligence training model 21 processes quasi-linear process parameter P1 (e.g., light-oil feed amount, steam usage amount, etc.) to rapidly calculate the intermediate parameter P2 (e.g., reaction rate), which is then provided to the second artificial intelligence training model 22 to reduce its computational burden.

The second artificial intelligence training model 22, based on a nonlinear regression algorithm, processes high-dimensional nonlinear data and finally outputs the predicted result P3 (e.g., yield or production rate), with strong tolerance to noise and missing data, thereby improving prediction accuracy. This architecture integrates the advantages of both linear and nonlinear models to effectively achieve precise modeling and optimization of chemical processes.

The above-described architecture of the present disclosure has been validated in experiments to exhibit high accuracy, with R² exceeding 0.95, indicating strong explanatory power of the model for data variability. The mean absolute percentage error (MAPE) is less than 0.2%, demonstrating that the deviation between predicted data and actual data is minimal, thus providing reliable decision support for chemical process optimization.

It should be noted that R² is a statistical metric used to measure the explanatory power of a regression model regarding data variability. The value ranges between 0 and 1, with values closer to 1 indicating stronger explanatory power for the target data and higher model fitness.

In the embodiment of the present disclosure, R² is used to evaluate prediction capability of the serial artificial intelligence training model. An R² value exceeding 0.95 indicates high accuracy and excellent adaptability of the model to chemical process data, thereby effectively supporting production decisions.

The mean absolute percentage error (MAPE) is a metric used to measure the accuracy of a prediction model, indicating the average percentage error between predicted values and actual values. A smaller MAPE value represents a smaller deviation between the predicted values and actual values, and thus having a higher model accuracy.

In the embodiment of the present disclosure, MAPE is less than 0.2%, indicating that the prediction deviation of the serial integration model is extremely low, which enables reliable prediction of the production output in the synthesis gas process and provides a high level of credibility for production optimization.

In one embodiment, if R² is too low or MAPE is too high, the serial artificial intelligence training module 2 will return to the training stage and continue training until both R² and MAPE reach ideal values.

In terms of hardware, the serial artificial intelligence training module 2 is suitable for operation in an environment that supports hardware-accelerated computing, such as a server equipped with high-performance graphics processing units (GPUs) or dedicated hardware accelerators. The module can run in a computing environment that supports deep learning and data modeling frameworks, enabling efficient computation of both linear and nonlinear regression models. The hardware configurations can significantly improve training speed and prediction accuracy, thereby achieving precise modeling and optimization of chemical processes.

### Profit Optimization Module

Further referring to FIG. 1, the profit optimization module 3 has a nature-inspired algorithm built therein, which simulates natural mechanisms or phenomena to search for optimal solutions of chemical process parameters in order to maximize economic benefits.

In some embodiments of the present disclosure, the nature-inspired algorithm can be at least one of genetic algorithm (GA), particle swarm optimization (PSO), ant colony optimization (ACO), and simulated annealing (SA).

The profit optimization module 3 is connected in data communication with the serial artificial intelligence training module 2, so as to synchronize and utilize the data and intelligent models from the serial artificial intelligence training module 2. The profit optimization module 3 further receives the data predicted and outputted from the serial artificial intelligence training module 2, such as the predicted result P3 (e.g., predicted yields or production rates of synthesis gas under various operating conditions).

The profit optimization module 3 is configured to receive at least an economic parameter P4 externally input. The economic parameter P4 can include at least one of a revenue parameter and an expenditure parameter. The revenue parameter can be a product selling price, and the expenditure parameter can be at least one of a raw material price and an energy cost (e.g., steam cost, electricity cost, and/or fuel cost).

The profit optimization module 3 utilizes the nature-inspired algorithm to calculate a production decision Pf based on a demand amount of a product, in combination with the economic parameter P4 and the data from the serial artificial intelligence training module 2 (e.g., the predicted results P3 under different operating conditions), while taking into account operational boundary constraints (e.g., operational upper and lower limit factors).

The production decision Pf includes recommended process operating conditions, such as a light-oil feed amount, a steam usage amount, a reaction temperature, a reaction pressure, and a carbon dioxide reflux amount, so that the process can meet the demand quantity while maximizing profit or minimizing cost.

In one embodiment of the present disclosure, the profit optimization module 3 is centered around an objective function, such as a profit maximization function or a cost minimization function, and is configured to determine optimized chemical process operating conditions through a recursive iteration (RC) approach.

It should be noted that, in the embodiment of the present disclosure, the term “considering operational boundary constraints” refers to the requirement that, when the profit optimization module 3 utilizes a nature-inspired algorithm to determine an optimal production decision, the allowable safety range and chemical theoretical range of each process parameter in actual production must be taken into account. These operational boundary constraints are derived from historical production data outputted by the big data database construction module 1, equipment operation manuals, technical specifications, or preset constraint parameters defined by on-site operators. For example, parameters such as reactor operating temperature, pressure, light oil feed rate, steam consumption, and CO₂ recycle rate, typically have explicitly defined upper and lower limits, which are established to prevent exceeding equipment safety thresholds or violating chemical process design requirements.

In practice, these upper and lower limit values can be directly input into the profit optimization module as constraint conditions, and incorporated into the objective function computation along with the economic parameter (e.g., product selling price, raw material and energy costs) and the predicted result (e.g., product yield or production rate). During the search for the optimal solution, the nature-inspired algorithm uses these constraints to restrict the range of candidate solutions, ensuring that the process operation parameters obtained in each iteration fall within a safe and feasible range. If a parameter combination generated by the algorithm exceeds the predefined range, a correction mechanism may be applied to adjust the parameters back into the acceptable range.

In addition to the operational limits of the equipment, the operational boundary constraints may further include environmental regulations, product quality requirements, and other practical conditions at the production site, such as reactant purity and equipment aging status. By incorporating these constraint conditions, the system can provide a production decision that is not only economically optimized to meet market demand, but also safe and practically feasible for real-world implementation.

The profit optimization module 3 utilizes the prediction result P3 of the serial artificial intelligence training module 2 as a starting point and further incorporates the economic parameter P4 (e.g., raw material price, energy cost, and product price) with the nature-inspired algorithm (e.g., particle swarm optimization and genetic algorithm) to compute the optimal operating parameters, thereby achieving the goal of maximizing economic profits. Through a recursive iteration process, the model repeatedly incorporates the prediction result of the serial artificial intelligence training module 2 into the iterative process to dynamically adjust and optimize the production conditions.

For example, a user can input a demand amount of a product into the system. Based on the demand amount, the profit optimization module 3 generates a production decision by comprehensively considering the predicted result P3 under different operating conditions and the economic parameter P4. The production decision includes optimal process parameters, such as the raw material ratio, operating temperature, and pressure, thereby enabling the process to satisfy the target production output while maximizing profit and minimizing cost.

The profit optimization module 3 is suitable for operation in a hardware environment with high computational capability, including multi-core and high-frequency processors, to support intensive iterative calculations and optimization tasks. To further enhance computational efficiency, a graphics processing unit (GPU) or a dedicated hardware accelerator can be employed, which is particularly suitable for high-computation-demand algorithms such as particle swarm optimization and genetic algorithms. The module can be deployed on a local server, an enterprise data center, or a cloud platform that supports high-performance computing, thereby enabling flexible adaptation to economic optimization requirements across multiple scenarios.

It should be noted that the profit optimization module 3 is required to take into account constraint conditions, such as operational upper and lower limits, to reflect the actual operating limits of the equipment (e.g., the safe operating range of temperature and pressure). The product demand must meet specified requirements in terms of quantity or purity. Environmental regulations may also impose constraints, such as limits on carbon dioxide emissions or compliance with safety standards.

Through the profit optimization module 3 described above, the system of the present disclosure enables accurate and real-time cost-benefit analysis of parameters in a synthesis gas process (e.g., light-oil feed amount, carbon dioxide reflux amount), thereby further improving overall chemical production profitability or reducing energy consumption.

### Visualization Interface Module

Further referring to FIG. 1, the visualization interface module 4 is configured to visually present the production decision Pf of the profit optimization module 3. The production decision Pf includes suggested process operation parameters such as light-oil feed amount, steam usage, reaction temperature, reaction pressure, and carbon dioxide reflux amount.

More specifically, the visualization interface module 4 can be defined as a real-time economic navigation module, which integrates all computations into a single operating interface (e.g., an internal company web page or application) using Python or other open-source tools. The visualization interface module 4 allows on-site operators or operational decision-makers to input the product demand and pricing information in real time so that the system automatically calculates and returns the optimal operating parameters and predicted profit, which helps reduce decision-making time and trial-and-error costs.

More specifically, the chemical process optimization system 100 of the embodiment of the present disclosure can ultimately present integrated data processing and optimization results from the serial integration model via the visualization interface, enabling the user to view model outputs in real time and easily operate the system. The interface allows the user to input operation parameters. For example, the user can input the demand amount of the product and the economic parameter, such as the raw material price, directly on the interface. The information is transmitted to the profit optimization module 3 for real-time computation.

Multi-scenario simulation enables the simulation of operational conditions under various scenarios (e.g., high demand or low demand, high price or low price), and visualizes output data such as yield, cost, and profit under different conditions through bar charts, radar charts, or heatmaps. Via a display or a control interface, the system provides immediate feedback on the optimal operating conditions, such as recommending a 3% reduction in light-oil usage or a 2% reduction in steam usage, so as to allow real-time adjustments to actual production settings. The visualization interface effectively reduces human error and decision-making time during chemical production adjustments, thereby improving the feasibility of implementing the technical solutions in actual plant operations.

### Example of Synthesis Gas Process

The following is an example of the chemical process optimization system 100 being applied on a synthesis gas process to enhance operational efficiency. The synthesis gas process involves a reforming reaction. The primary raw materials include methane (CH₄) and water vapor (H₂O), used to produce synthesis gas (a mixture of CO and H₂). The reaction equations are as follows:

CH₄+H₂O↔CO+3H₂ (main reaction)

CH₄+CO₂↔2CO+2H₂

CO₂+H₂↔CO+H₂O

In the first artificial intelligence training model 21 (i.e., a linear regression model), the process parameters P1, such as light-oil feed amount, steam usage, reaction temperature, reaction pressure, and/or CO₂ reflux amount, are inputted. The first artificial intelligence training model 21 then outputs a predicted intermediate parameter P2 (e.g., a reaction rate).

In the second artificial intelligence training model 22 (i.e., a nonlinear regression model such as XGBoost Regressor), the predicted intermediate parameter P2 (i.e., reaction rate) outputted from the first artificial intelligence training model 21 and the process parameters P1 (e.g., light-oil feed amount, steam usage, reaction temperature, reaction pressure, and CO₂ reflux amount) originally inputted in the first artificial intelligence training model 21 are provided as inputs. The second artificial intelligence training model 22 then outputs a predicted result P3 (e.g., the yield of synthesis gas).

The profit optimization module (embedded with PSO) uses an objective function defined as: maximize profit(x)=(product price×synthesis gas yield)−(raw material cost+energy cost), and considers constraint conditions such as ensuring that reaction temperature and reaction pressure do not exceed safety limits, and the output yield must meet customer demand.

In terms of result comparison, under the same light oil feed conditions, using the integral models of the present embodiment can increase the synthesis gas yield by 2%. Alternatively, under the condition of achieving the same synthesis gas yield, the integral models of the present embodiment enables a reduction in light oil feed by 2% and a reduction in steam consumption by 3%.

Based on the above implementation case, the chemical process optimization system 100 of the present embodiment is capable of promptly responding to variations in market conditions and process parameters (e.g., fluctuations in raw material prices), thereby achieving the goals of cost reduction and profit enhancement.

### Chemical Process Optimization Method Based on Serial Integration Models

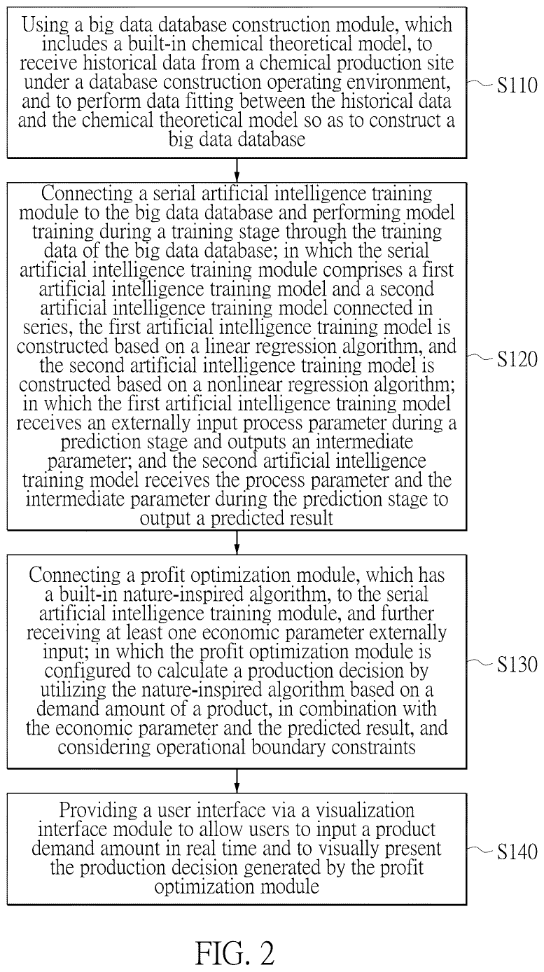

Referring to FIG. 2, an embodiment of the present disclosure provides a chemical process optimization method based on serial integration models, including steps S110, S120, S130, and S140.

Step S110 includes: using a big data database construction module, having a chemical theoretical model built (embedded) therein, to receive historical data collected from a chemical production site under a database construction operating environment, and to perform data fitting between the historical data and the chemical theoretical model so as to construct a big data database.

Step S120 includes: connecting a serial artificial intelligence training module to the big data database and performing model training through training data in the big data database during a training stage. The serial artificial intelligence training module includes a first artificial intelligence training model and a second artificial intelligence training model that are connected in series. The first artificial intelligence training model is constructed based on a linear regression algorithm, and the second artificial intelligence training model is constructed based on a nonlinear regression algorithm. During a prediction stage, the first artificial intelligence training model receives at least one externally input process parameter and outputs at least one intermediate parameter. The second artificial intelligence training model receives the process parameter and further receives the intermediate parameter during the prediction stage to calculate and output at least one predicted result.

Step S130 includes: connecting a profit optimization module, having a nature-inspired algorithm built (embedded) therein, to the serial artificial intelligence training module to receive the predicted result and further receive at least one externally input economic parameter. The profit optimization module is configured to utilize the nature-inspired algorithm to calculate a production decision based on a demand amount of a product, in combination with the economic parameter and the predicted result, and further considering at least one operational boundary constraint.

Step S140 includes: using a visualization interface module to allow a user to input the demand amount of the product in real time and to visually present the production decision generated by the profit optimization module.

### Beneficial Effects of the Embodiments

In conclusion, the technical solution of the present embodiment achieves precise modeling and maximized economic benefits for chemical processes by integrating big data, artificial intelligence, and optimization algorithms within a chemical process optimization system based on serial integration models. The system includes a big data database construction module, a serial artificial intelligence training module, a profit optimization module, and a visualization interface module. The modules operate in coordination to address issues commonly found in conventional chemical processes, such as data incompleteness, inaccurate modeling, and inefficient decision-making.

Firstly, the big data database construction module combines a chemical theoretical model with historical data from chemical production sites to construct a big data database with physical significance.

Therefore, the big data database construction module provides a highly reliable data foundation for subsequent modeling.

Secondly, the serial artificial intelligence training module adopts a serial architecture of linear and nonlinear regression models, leveraging the fast computation capability of the linear model and the high accuracy of the nonlinear model. The serial artificial intelligence training module enables precise modeling and prediction of complex chemical process conditions and reactions. The module can dynamically process the relationships among process parameters, intermediate parameters, and predicted results, significantly improving prediction accuracy.

The profit optimization module incorporates a nature-inspired algorithm and calculates optimal process operating conditions by combining the predicted results from the serial artificial intelligence models with external economic parameters (e.g., raw material cost, energy consumption, and product price), which enables the process to meet the required production output while maximizing profit or minimizing cost.

Additionally, the module considers operational boundary constraints, environmental regulations, and safety requirements to ensure the feasibility and compliance of the results.

Finally, the visualization interface module presents the decision results generated from the system in an intuitive manner using various formats, supports on-site operation and multi-scenario simulation, and improves decision-making efficiency and accuracy. The embodiment of the present disclosure enables effective chemical process optimization and provides improvements in both production performance and economic outcomes.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chemical process optimization system based on serial integration models, comprising:
a big data database construction module having a chemical theoretical model built therein and being configured to receive historical data collected from a chemical production site under a database construction operating environment, and to perform data fitting between the historical data and the chemical theoretical model, so as to construct a big data database;
a serial artificial intelligence training module being connected to the big data database and configured to perform model training through training data in the big data database during a training stage, wherein the serial artificial intelligence training module includes:
a first artificial intelligence training model being constructed based on a linear regression algorithm; and
a second artificial intelligence training model being constructed based on a nonlinear regression algorithm;
wherein, during a prediction stage, the first artificial intelligence training model receives at least a process parameter that is externally input and outputs at least an intermediate parameter, wherein the second artificial intelligence training model receives the process parameter and further receives the intermediate parameter during the prediction stage so as to calculate and output at least a predicted result; and
a profit optimization module having a nature-inspired algorithm built therein, wherein the profit optimization module is connected to the serial artificial intelligence training module;
wherein the profit optimization module is configured to receive at least an economic parameter that is externally input, and the profit optimization module is configured to utilize the nature-inspired algorithm to calculate a production decision based on a demand amount of a product, in combination with the economic parameter and the predicted result, and further considering at least an operational boundary constraint.

2. The chemical process optimization system according to claim 1, further comprising: a visualization interface module configured to allow a user to input the demand amount of the product in real time, and to visually present the production decision of the profit optimization module.

3. The chemical process optimization system according to claim 1, wherein the chemical theoretical model is implemented using a chemical simulation software with physical meaning, and the chemical simulation software is at least one of Aspen Plus, Aspen HYSYS, PRO/II, and Petro-SIM; wherein the historical data is historical production data collected from the chemical production site, and the training data includes process data, intermediate data, and product data.

4. The chemical process optimization system according to claim 3, wherein the first artificial intelligence training model adopts at least one of ordinary least squares (OLS), gradient descent, and regularized linear regression.

5. The chemical process optimization system according to claim 4, wherein the second artificial intelligence training model adopts at least one of polynomial regression, support vector regression (SVR), decision tree regression, random forest regression, neural network regression, nonlinear least squares, gaussian process regression (GPR), and XGBoost Regressor.

6. The chemical process optimization system according to claim 5, wherein the nature-inspired algorithm is at least one of genetic algorithm (GA), particle swarm optimization (PSO), ant colony optimization (ACO), and simulated annealing (SA).

7. The chemical process optimization system according to claim 6, wherein, during the training stage, the serial artificial intelligence training module is configured to train and cross-validate the first artificial intelligence training model and the second artificial intelligence training model separately by using the training data from the big data database.

8. The chemical process optimization system according to claim 1, wherein, in the serial artificial intelligence training module, the process parameter includes at least one of a light-oil feed amount, a steam usage amount, a reaction temperature, a reaction pressure, and a carbon dioxide reflux amount; wherein the intermediate parameter includes at least one of a reaction rate and a reaction conversion rate; and wherein the predicted result includes at least one of a product yield and a product production rate.

9. The chemical process optimization system according to claim 8, wherein the economic parameter includes at least one of a revenue parameter and an expenditure parameter; wherein the revenue parameter corresponds to a product selling price, and the expenditure parameter includes at least one of a raw material price and an energy cost.

10. The chemical process optimization system according to claim 1, wherein the profit optimization module is configured to analyze and output the production decision through a recursive iteration process based on a profit maximization function or a cost minimization function.

11. A chemical process optimization method based on serial integration models, comprising:
using a big data database construction module, having a chemical theoretical model built therein, to receive historical data collected from a chemical production site under a database construction operating environment, and to perform data fitting between the historical data and the chemical theoretical model, so as to construct a big data database;
connecting a serial artificial intelligence training module to the big data database, and performing model training through training data in the big data database during a training stage, wherein the serial artificial intelligence training module includes: a first artificial intelligence training model and a second artificial intelligence training model that are connected in series;
wherein the first artificial intelligence training model is constructed based on a linear regression algorithm, and the second artificial intelligence training model is constructed based on a nonlinear regression algorithm;
wherein, during a prediction stage, the first artificial intelligence training model receives at least a process parameter that is externally input and outputs at least an intermediate parameter;
wherein the second artificial intelligence training model receives the process parameter and further receives the intermediate parameter during the prediction stage so as to calculate and output at least a predicted result; and
connecting a profit optimization module having a nature-inspired algorithm built therein to the serial artificial intelligence training module;
wherein the profit optimization module is configured to receive at least an economic parameter that is externally input, and the profit optimization module is configured to utilize the nature-inspired algorithm to calculate a production decision based on a demand amount of a product, in combination with the economic parameter and the predicted result, and considering at least an operational boundary constraint.

12. The chemical process optimization method according to claim 11, further comprising:
using a visualization interface module to allow a user to input the demand amount of the product in real time, and visually present the production decision of the profit optimization module.
